(19) United States
(12) Patent Application Publication
(10) Pub. No.: US 2012/0306487 A1
(43) Pub. Date: Dec. 6, 2012

(54) ELECTRICAL CURRENT SENSING CIRCUIT, PRINTED CIRCUIT BOARD ASSEMBLY AND ELECTRICAL CURRENT SENSOR DEVICE WITH THE SAME

(75) Inventors: Ming Gao YAO, DongGuan (CN); Li Bing LIU, DongGuan (CN)

(73) Assignee: SAE Magnetics (H.K.) Ltd., Hong Kong (CN)

(21) Appl. No.: 13/245,052

(22) Filed: Sep. 26, 2011

(30) Foreign Application Priority Data
Jun. 3, 2011 (CN) 201110148989.7

(51) Int. Cl. G01R 33/09

(52) U.S. Cl. 324/252

(57) ABSTRACT

An electrical current sensing circuit of the present invention comprises a Wheatstone bridge circuit having at least four magnetoresistive elements connecting and a pair of output terminals, the magnetoresistive elements adapted for sensing an external magnetic field with a first direction generated by a carrying-current electrical conductor, and outputting a differential signal; and a negative feedback circuit connecting with the output terminals, actuated by the differential signal and generated a magnetic field with a second direction that is opposite to the first direction, thereby decreasing the impact of the temperature drift to the magnetoresistive element character. The present invention can eliminate the temperature drift under a changing environment and, in turn obtain an accurate output voltage.

This application claims the benefit of Chinese Patent Application No. 201110148989.7, filed on Jun. 3, 2011, the entire content of which is hereby incorporated by reference in this application.

### FIELD OF THE INVENTION

The present invention relates to an electrical current sensor device and, more particularly, to an electrical current sensing circuit with a negative feedback circuit for eliminating the impact of the temperature drift to the elements in the circuit under a changing environment.

### BACKGROUND OF THE INVENTION

Many types of electrical current sensors are known and are in wide use today throughout the electronics industry. Commonly, many of these sensors include a Hall effect generator that senses the magnetic field associated with an electrical current and, in turn, produces a Hall effect output voltage that is proportional to the magnetic field.

Hall effect generators generally comprise a layer of homogeneous semiconductor material, known as the Hall plate, constructed upon a dielectric substrate. An excitation current is applied to the Hall plate, when the Hall effect generator is placed in a magnetic field and supplied with excitation current, the Hall effect output voltage is produced in the Hall plate which is orthogonal to the magnetic field and the excitation current, and then the output voltage is measured out.

Various types of sensing device utilizing the Hall effect phenomena have been used in the past, as disclosed in U.S. Pat. No. 5,416,407. As shown in FIG. 1, the electrical current sensor 100 comprises an amplifier 102, a constant current source 104, a gapped toroid core (not shown) mounted on the component side of a printed circuit board (PCB) (not shown), a Hall effect generator 106 extending via its output leads from the PCB into the gap of the toroid core, and an inductive loop 108 positioned at the edge of the gap of the toroid core. Concretely, the Hall effect generator 106 comprises a standard design having a semiconductor Hall plate (not shown) mounted onto a dielectric substrate (not shown) within a sealed package with its constant current leads 112 and the Hall effect output voltage leads 114 extending therefrom.

During operation, an electrical conductor is inserted through a hole in the PCB. As electrical current flows through the conductor, a magnetic field is created within the toroid core and across the gap of the toroid core. The Hall effect generator 106 and the inductive loop 108 are therefore subjected to the magnetic field. The constant current source 104 supplies a temperature-compensated constant current to the Hall plate. As a result, the Hall effect generator 106 produces an output voltage that is proportional to the magnetic field concentrated onto its Hall plate, and this output voltage is then supplied to the amplifier 102 to be amplified to a useful level, finally an electrical current can be detected.

However, the above-mentioned electrical current sensor 100 can only detect a higher current due to the Hall effect, and the signal of the output voltage is lower with a poor accuracy. Generally, a distortion and a temperature drift are presented on the circuit, which decreases the measurement accuracy of the electrical current. Moreover, the sensitivity of the Hall element in the Hall effect generator 106 is insufficient due to the alternating and transient current.

Thus, there is a need for an improved electrical current sensor with an improved electrical current sensing circuit to overcome the above drawbacks.

### SUMMARY OF THE INVENTION

One aspect of the present invention is to provide an electrical current sensing circuit with a negative feedback circuit which can eliminate the temperature drift under a changing environment and, in turn obtain an accurate output voltage.

Another aspect of the present invention is to provide a printed circuit board assembly with an electrical current sensing circuit, which can eliminate the temperature drift under a changing environment and, in turn obtain an accurate output voltage.

Yet one aspect of the present invention is to provide an electrical current sensor device with an electrical current sensing circuit, which can detect a low current and a high current, and eliminate the temperature drift under a changing environment and, in turn obtain an accurate output voltage, finally improve the measurement accuracy.

To achieve above objectives, an electrical current sensing circuit of the present invention comprises a Wheatstone bridge circuit having at least four magnetoresistive elements connecting and a pair of output terminals, the magnetoresistive elements adapted for sensing an external magnetic field with a first direction generated by a carrying-current electrical conductor, and outputting a differential signal; and a negative feedback circuit connecting with the output terminals, actuated by the differential signal and generated a magnetic field with a second direction that is opposite to the first direction, thereby eliminate the impact of the temperature drift to the magnetoresistive element character.

As an embodiment, the four magnetoresistive elements are divided into a first element pair and a second element pair that have two opposed pinning directions, which are perpendicular to the first direction of the external magnetic field.

Preferably, the negative feedback circuit comprises a preamplifier and a main wire, the preamplifier is connected with the output terminals, and the main wire is configured between the first element pair and second element pair and the configuring direction of the main wire is vertical with the pinning directions of the first element pair and the second element pair.

Preferably, the distance between the first element pair and the carrying-current electrical conductor is different from that between the second element pair and the carrying-current electrical conductor.

Alternatively, the distance between the first element pair and the carrying-current electrical conductor is the same with that between the second element pair and the carrying-current electrical conductor.

Preferably, the first element pair has a first sensitivity and a first saturation point, and the second element pair has a second sensitivity and a second saturation point.

As another embodiment, the first sensitivity is equal to the second sensitivity, and the first saturation point is not equal to the second saturation point.

As yet one embodiment, the first sensitivity is not equal to the second sensitivity, and the first saturation point is not equal to the second saturation point.

A printed circuit board assembly of the present invention comprises an electrical current sensing circuit, an analog-to-digital converter and a central processing unit connecting. The electrical current sensing circuit comprises a Wheatstone bridge circuit having at least four magnetoresistive elements connecting and a pair of output terminals, the magnetoresistive elements adapted for sensing an external magnetic field with a first direction generated by a carrying-current electrical conductor, and outputting a differential signal; and a negative feedback circuit connecting with the output terminals, actuated by the differential signal and generated a magnetic field with a second direction that is opposite to the first direction, thereby eliminating the impact of the temperature drift to the magnetoresistive element character.

As an embodiment, the four magnetoresistive elements are divided into a first element pair and a second element pair that have two opposed pinning directions, which are perpendicular to the first direction of the external magnetic field.

Preferably, the negative feedback circuit comprises a preamplifier and a main wire, the preamplifier is connected with the output terminals, and the main wire is configured between the first element pair and second element pair and the configuring direction of the main wire is vertical with the pinning directions of the first element pair and the second element pair.

Preferably, the distance between the first element pair and the carrying-current electrical conductor is different from that between the second element pair and the carrying-current electrical conductor.

Alternatively, the distance between the first element pair and the carrying-current electrical conductor is the same with that between the second element pair and the carrying-current electrical conductor.

Preferably, the first element pair has a first sensitivity and a first saturation point, and the second element pair has a second sensitivity and a second saturation point.

As another embodiment, the first sensitivity is equal to the second sensitivity, and the first saturation point is not equal to the second saturation point.

As yet one embodiment, the first sensitivity is not equal to the second sensitivity, and the first saturation point is not equal to the second saturation point.

An electrical current sensor device of the present invention comprises at least one printed circuit board assembly, a holder for holding the printed circuit board assembly, a shielding cover covering on the holder for shielding an external magnetic field generated by external environment and a display device formed on the shielding cover and connected with the printed circuit board assembly. The printed circuit board assembly comprises an electrical current sensing circuit comprising a Wheatstone bridge circuit having at least four magnetoresistive elements connecting and a pair of output terminals, the magnetoresistive elements adapted for sensing an external magnetic field with a first direction generated by a carrying-current electrical conductor, and outputting a differential signal; and a negative feedback circuit connecting with the output terminals, actuated by the differential signal and generated a magnetic field with a second direction that is opposite to the first direction, thereby eliminating the impact of the temperature drift to the magnetoresistive element character.

In comparison with the prior art, firstly, the present invention applies the magnetoresistive elements to form a Wheatstone bridge circuit for replacing the Hall effect generator, the sensitivity of the magnetoresistive elements is higher than the Hall element. Secondly, the electrical sensing circuit of the present invention provides a negative feedback circuit which can eliminate the impact of the temperature drift to the magnetoresistive elements under a changing environment and, in turn obtain an accurate output voltage. Moreover, the electrical current sensor device of the present invention further includes a shielding cover for shielding the external magnetic field which is generated by the external space (such as the earth) or the outer equipments (such as a motor near the electrical current sensor device), and preventing the external magnetic field to affect the magnetoresistive elements, thereby improved the measurement accuracy of the current.

Other aspects, features, and advantages of this invention will become apparent from the following detailed description when taken in conjunction with the accompanying drawings, which are a part of this disclosure and which illustrate, by way of example, principles of this invention.

### BRIEF DESCRIPTION OF THE DRAWINGS

The accompanying drawings facilitate an understanding of the various embodiments of this invention. In such drawings:

FIG. 1 is a block diagram of a conventional the electrical current sensor;

FIG. 2 is a block diagram of an electrical current sensing circuit according to one embodiment of the present invention;

FIG. 3 is a structure view of the GMR element of the electrical current sensing circuit;

FIG. 4 shows the detailed structure view of the electrical current sensing circuit;

FIG. 5 shows a simplified view that shows the operation of the electrical current sensing circuit;

FIG. 6a shows one arrangement of the sensitivity and saturation point of the GMR elements of the Wheatstone bridge circuit;

FIG. 6b shows another arrangement of the sensitivity and saturation point of the four GMR elements of the Wheatstone bridge circuit;

FIG. 7a is a simplified view of electrical current sensing circuit shown in FIG. 5;

FIG. 7b is a simplified view of electrical current sensing circuit according to another embodiment of the present invention;

FIG. 8 is a block diagram of a printed circuit assembly (PCBA) according to one embodiment of the present invention;

FIG. 9a is a perspective view of an electrical current sensor device according to one embodiment of the present invention; and

FIG. 9b is an exploded view of the electrical current sensor device shown in FIG. 9a.

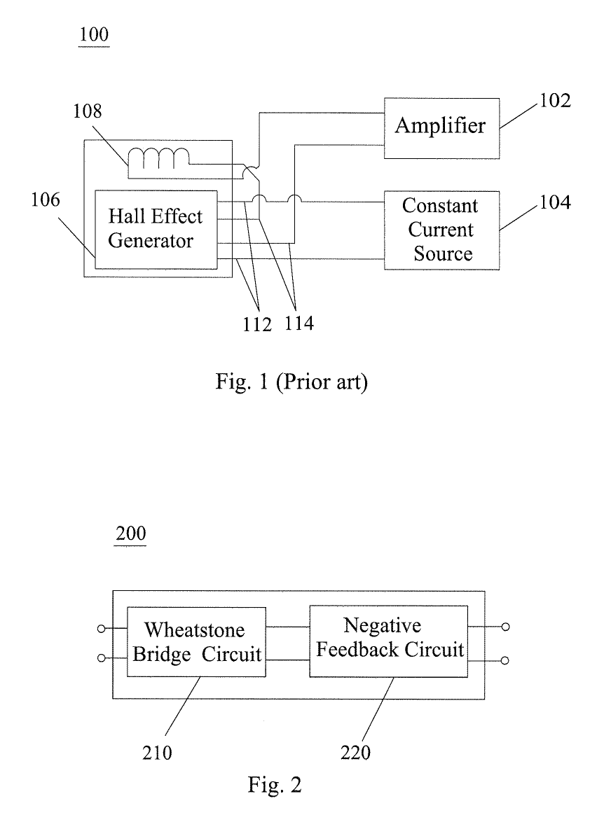

### DETAILED DESCRIPTION OF ILLUSTRATED EMBODIMENTS

Various preferred embodiments of the invention will now be described with reference to the figures, wherein like reference numerals designate similar parts throughout the various views. As indicated above, the invention is directed to an electrical current sensing circuit having a negative feedback circuit, which can eliminate the temperature drift of the circuit under a changing environment and, in turn obtain an accurate output voltage.

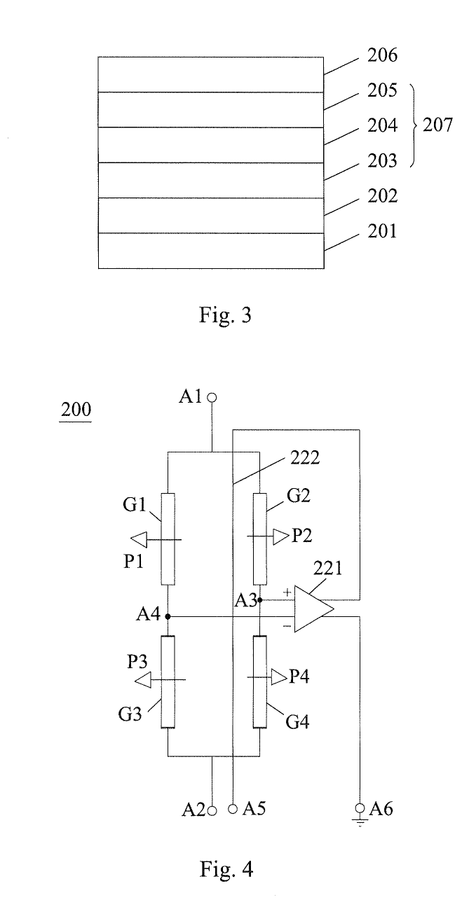

FIG. 2 shows a block diagram of an electrical current sensing circuit 200 according to one embodiment of the present invention. As shown, the electrical current sensing circuit 200 includes a Wheatstone bridge circuit 210 and a negative feedback circuit 220 connecting with the Wheatstone bridge circuit 210. Concretely, the Wheatstone bridge circuit 210 is composed of four magnetoresistive elements, such as giant magnetoresistive (GMR) elements in this embodiment. Within the contemplation of the present invention, the magnetoresistive element also can be the tunnel magnetoresistive (TMR) or anisotropic magnetoresistive (AMR) to form the Wheatstone bridge circuit 210.

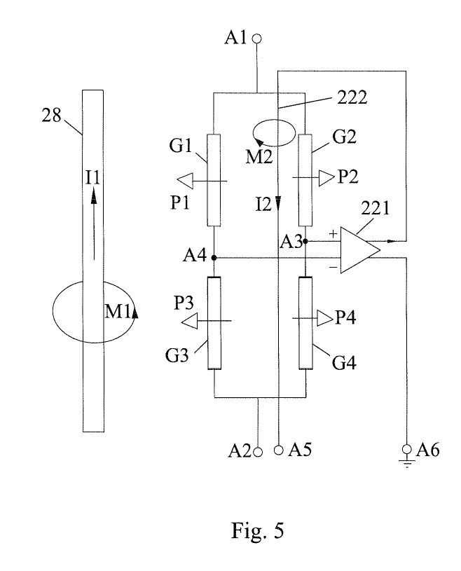

FIG. 3 shows the structure of the GMR element, which includes a substrate layer 201, a buffer layer 202, a fixed layer 207 and a capping layer 206 laminated in turns. Concretely, the fixed layer 207 includes a pinning layer 205 for pinning the magnetization direction in a fixed direction, a free layer 203 with a magnetization direction that varies with an external magnetic field, and a space layer 204 sandwiched between the pinning layer 205 and the free layer 203 serving as a non-magnetic electric conductor. As known, the resistance of the GMR element varies with the angle between the pinning direction of the pinning layer 205 and the magnetization direction of the free layer 203. And when the GMR element locates in an external magnetic field, the direction of the free layer 203 will change depending on the external magnetic field, that is, the angle between the pinning direction of the pinning layer 205 and the magnetization direction of the free layer 203. As a result, the resistance of the GMR element changes, which causes an output voltage to generate.

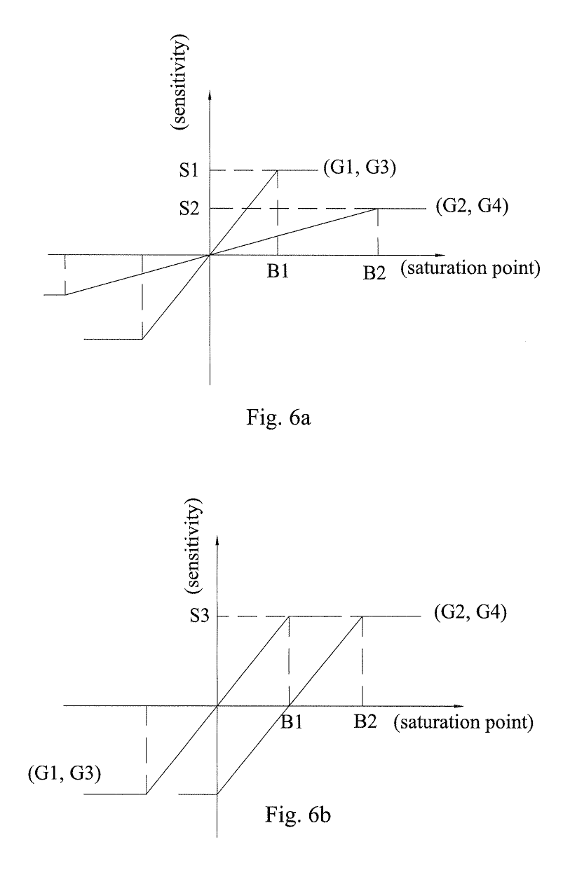

Now the detailed structure of the electrical current sensing circuit 200 is described as following. As shown in FIG. 4, the Wheatstone bridge circuit 210 according to a first embodiment of the present invention comprises four GMR elements called for short G1, G2, G3, and G4, each of GMR elements has a pinning direction indicated by P1, P2, P3 and P4. Concretely, the four GMR elements are divided into a first element pair and a second element pair, and the G1 and G3 are composed of the first element pair, and the G2 and G4 are composed of the second element pair. More specifically, the pinning directions P1 and P3 are the same, and the pinning directions P2 and P3 are the same and opposite to the P1 and P3. Furthermore, the Wheatstone bridge circuit 210 provides a pair of power input terminals and a pair of output terminals. For example, one end A1 between G1 and G2, and the other end A2 between G3 and G4, serve as the two ends of the power input terminals; one end A3 between G2 and G4, and the other end A4 between G1 and G3, serve as the two ends of the output terminals. Alternatively, the ends A1 and A2 also can serve as the output terminals, and the ends A3 and A4 serve as the power input terminals. The output voltage depends on the resistance values of the G1, G2, G3, and G4, which vary with the magnetization directions under the external magnetic field.

Within the contemplation of the present invention, the negative feedback circuit 220 is connected with to the output terminals A3, A4, as shown in FIG. 4 again. The negative feedback circuit 220 includes a preamplifier 221 and a main wire 222. Concretely, the positive input terminal of the preamplifier 221 is connected with the output terminal A3, and the negative input terminal of the preamplifier 221 is connected with the output terminal A4, the main wire 222 is connected with the positive output terminal A5 of the preamplifier 221 and configured between the first element pair and the second element pair of the GMR elements, and the negative output terminal A6 is connected to the ground. Preferably, the configuring direction of the main wire 222 is vertical with the pinning directions P1, P2, P3, P4 of the GMR elements G1, G2, G3, G4, so that the direction of the differential current I2 is vertical with the pinning directions P1-P4 of the GMR elements G1-G4.

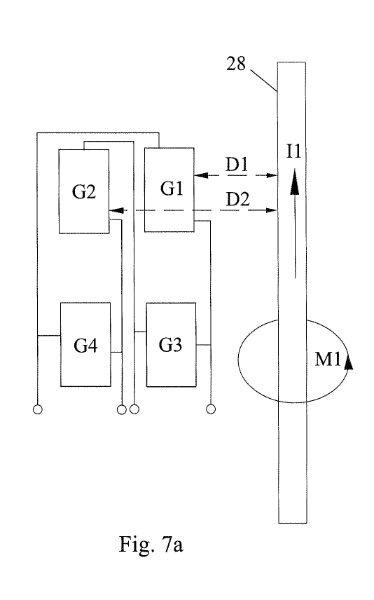

FIG. 5 shows a simplified view that shows the operation of the electrical current sensing circuit 200. When a carrying-current electrical conductor 28 is supplied a current I1, a magnetic field with a first direction M1 is generated around the electrical conductor 28, therein the first direction M1 is perpendicular to the pinning directions P1-P4. When the carrying-current electrical conductor 28 is positioned close to the electrical current sensing circuit 200, the resistance of the GMR elements G1-G4 of the electrical current sensing circuit 200 varies with the outer magnetic field, which causes a differential voltage to output on the output terminals A3 and A4. The differential voltage goes through the preamplifier 221, and a current I2 goes through the main wire 222, which induces a magnetic field with a second direction M2. Concretely, the current I2 is opposite to the current I1 of the carrying-current electrical conductor 28, thus the second direction M2 of the magnetic field induced by the current I2 is opposite to the first direction M1 of the magnetic field. More specifically, the magnetic field with the first direction M1 increases the differential voltage of the output terminals A3, A4, and the differential voltage is then inputted to the preamplifier 221. Thus the current I2 generated in the main wire 222 is increased and, in turn, the magnetic field with the second direction M2 is increased. Since the second direction M2 is opposite the first direction M1, thus the magnetic field with the first direction M1 is reduced, until a dynamic equilibrium is achieved and the differential voltage of the output terminals A3, A4 is stable. Therefore, the magnetic field with opposed phase and direction M2 can reduce the differential voltage and the current I2 on the output of the electrical current sensing circuit 200, which forms a negative feedback system. As a result, the temperature drift phenomenon is eliminated by this negative feedback circuit 220 under a changing environment, that is the impact of the temperature drift to the GMR element character is eliminated, causing that the differential output voltage between the terminal A5 and A6 is stable and accurate. The differential output voltage is proportional with the external magnetic field M1, and as the temperature drift phenomenon is eliminated by the negative feedback circuit 220, thus the measurement accuracy of the current of the carrying-current electrical conductor 28 is improved.

Preferably, each of the GMR elements of the present invention can be separated into multiple square segments which are connected by electrodes. Basing on this configuration, the stability and the reliability of the GMR element can be improved significantly.

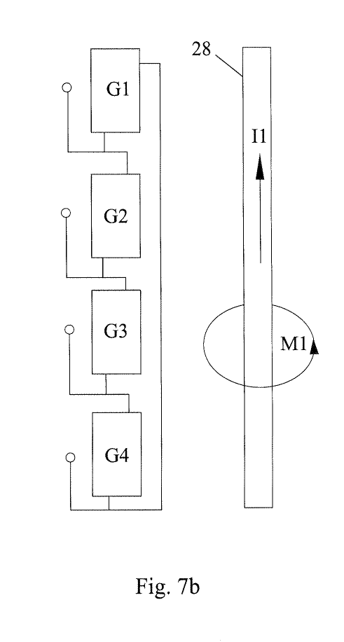

Preferably, in this embodiment, the first element pair and the second element pair of the GMR elements have two different sensitivities, that is, the G1 and G3 have the same sensitivity S1, and G2 and G4 have the same sensitivity S2, therein S1 is not equal to S2. Alternatively, S1 is larger than S2 for sensing the lower current, and S2 is smaller for sensing the higher current. The detailed date can be configured during the actual manufacturing process. Furthermore, the saturation points of the two pairs are different. Concretely, the saturation point of the first element pair is smaller than that of the second element pair. More concretely, the saturation point of G1 and G3 is B1, and the saturation point of G2 and G4 is B2, as show in FIG. 6a. Basing on this design, the G1 and G3 will be saturated when the external magnetic field is increased to point B1, and the G2 and G4 work normally. Thus, under a lower magnetic field, namely a smaller current, the G2 and G4 with a lower sensitivity S2 is inactive and is corresponding to a load, and the G1 and G3 with a higher sensitivity S1 is active to detect the smaller current on the carrying-current electrical conductor 28; under a higher magnetic field, namely a bigger current, the G1 and G3 with a higher sensitivity S1 will be saturated and is corresponding to a load, and the G2 and G4 with a lower sensitivity S2 is active to detect the bigger current on the carrying-current electrical conductor 28.

Alternatively, the sensitivity (S3) of the four GMR elements G1-G4 is the same, and the saturation points have two types as mentioned above, referring to FIG. 6b.

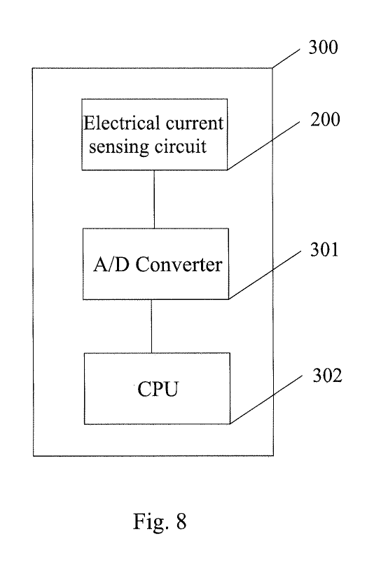

In this embodiment, when the carrying-current electrical conductor 28 is positioned besides the electrical sensing circuit 200, the distance D1 between the first element pair and the carrying-current electrical conductor 28 is different from the distance D2 between the second element pair and the carrying-current electrical conductor 28, as shown in FIG. 7a that is a simplified view of FIG. 5. Concretely, the distance D1 between the G1, G3 and the carrying-current electrical conductor 28 is smaller than the distance D2 between the G2, G4 and the carrying-current electrical conductor 28. Here, the negative feedback circuit 220 is omitted in this figure.

Alternatively, the G1, G2, G3, G4 have the same distance to the carrying-current electrical conductor 28, as illustrated in FIG. 7b, which is a simplified view. The four GMR elements are set in a line. Concretely, G1 and G3 have a higher sensitivity S1 and lower saturated point P1 for detecting a lower current on the carrying-current electrical conductor 28, and G2 and G4 have a lower sensitivity S2 and higher saturation point B2 for detecting a higher current on the carrying-current electrical conductor 28, which the sensitivities and the saturation points can be configured as shown in FIG. 6a. Of course, they also can be configured as shown in FIG. 6b.

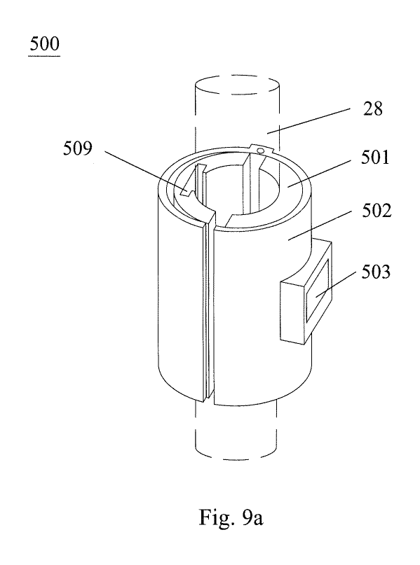

FIG. 8 shows a PCBA 300 having the electrical current sensing circuit 200 according to the present invention. The PCBA 300 further includes an analog-to-digital (A/D) converter 301 and a central processing unit (CPU) 302 connecting. The A/D converter 301 converts the output voltage outputting from the electrical sensing circuit 200, and then calculated by the CPU 302. The PCBA 300 includes all technical features of the electrical sensing circuit 200 described above, and other elements of the PCBA 300 are familiar to one person ordinarily skilled in the art, thus detailed description is omitted here.

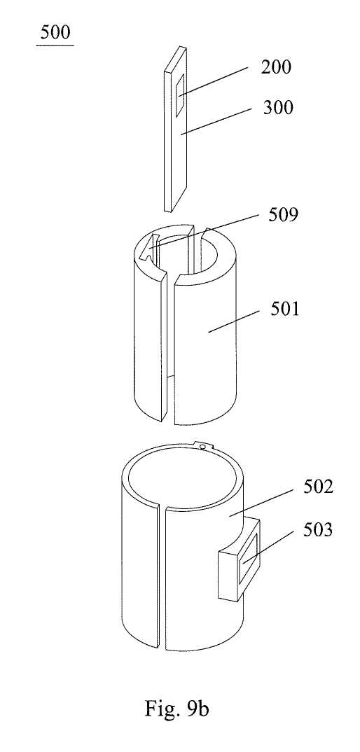

FIGS. 9a-9b show an electrical current sensor device according to one embodiment of the present invention. As shown, the electrical current sensor device 500 includes at least one PCBA 300, a holder 501 for holding the PCBA 300, a shielding cover 502 covering on the holder 501, and a display device 503 formed on the shielding cover 502 and connected with the PCBA 300. Concretely, the holder 501 is in a column shape and a passage (not labeled) is provided to allow the carrying-current electrical conductor 28 to pass through. More concretely, the holder 501 made of ceramic material, and the holder 501 can be separated into two pieces, alternatively it can be an integrated unity. At least one slot 509 is formed on the inner wall of the holder 501 for accommodating the PCBA 300. And the shielding cover 502 is made of permalloy material and in a column shape according to the holder 501, which is adapted for shielding the magnetic field generated by the external space (for example the earth), and the outer equipment (such as the motor near the electrical current sensor device 500). Due to the shielding cover 502, the GMR elements will only sense the magnetic field generated by the carrying-current electrical conductor 28, the differential output voltage from the Wheatstone bridge circuit 210 is linearly proportioned with the current through the carrying-current electrical conductor 28, thus measurement accuracy of the electrical current is improved.

Combining with FIG. 5 and FIG. 9a, during operation, the electrical conductor 28 is inserted into the passage of holder 501 of the electrical current sensor device 500. When a current passes through the carrying-current electrical conductor 28, a magnetic field is then generated. Thus, the resistance of the GMR elements G1-G4 of the electrical current sensing circuit 200 on the PCBA 300 varies with the magnetic field, which causes a differential voltage to output on the output terminals A3 and A4 (referring to FIG. 5). The differential voltage goes through the preamplifier 221, and a current I2 goes through the main wire 222, which induces a magnetic field with a second direction M2. Concretely, the current direction 12 is opposite to the current I1 of the carrying-current electrical conductor 28, thus the second direction M2 of the magnetic field induced by the current I2 is opposite to the first direction M1 of the magnetic field. More specifically, the magnetic field with the first direction M1 increases the differential voltage of the output terminals A3, A4, and the differential voltage is then inputted to the preamplifier 221. Thus the current I2 generated in the main wire 222 is increased and, in turn, the magnetic field with the second direction M2 is increased. Since the second direction M2 is opposite the first direction M1, thus the magnetic field with the first direction M1 is reduced, until a dynamic equilibrium is achieved and the differential voltage of the output terminals A3, A4 is stable. Therefore, the magnetic field M2 with opposed phase and direction compared with the magnetic field M1 can reduce the differential voltage and the current I2 on the output of the electrical current sensing circuit 200, which forms a negative feedback system. As a result, the temperature drift phenomenon is eliminated under a changing environment, that is the impact of the temperature drift to the GMR element character is eliminated, causing that the output voltage between the terminal A5 and A6 is stable and accurate. The differential output voltage is proportional with the outer magnetic field M1, the differential voltage outputted from the negative feedback circuit 220 is then converted and calculated by the A/D converter 301 and the CPU 302 in the PCBA 300, and the current value is finally displayed on the display device 503. Since the temperature drift phenomenon is eliminated by the negative feedback circuit 220, thus the output voltage is improved by the negative feedback circuit 220, therefore the measurement accuracy of the current of the carrying-current electrical conductor 28 is improved finally.

While the invention has been described in connection with what are presently considered to be the most practical and preferred embodiments, it is to be understood that the invention is not to be limited to the disclosed embodiments, but on the contrary, is intended to cover various modifications and equivalent arrangements included within the spirit and scope of the invention.

What is claimed is:

1. An electrical current sensing circuit comprising:
a Wheatstone bridge circuit having at least four magnetoresistive elements connecting and a pair of output terminals, the magnetoresistive elements adapted for sensing an external magnetic field with a first direction generated by a carrying-current electrical conductor, and outputting a differential signal; and
a negative feedback circuit connecting with the output terminals, actuated by the differential signal and generated a magnetic field with a second direction that is opposite to the first direction, thereby eliminating the impact of the temperature drift to the magnetoresistive element character.

2. The electrical current sensing circuit according to claim 1, wherein the four magnetoresistive elements are divided into a first element pair and a second element pair that have two opposed pinning directions, which are perpendicular to the first direction of the external magnetic field.

3. The electrical current sensing circuit according to claim 2, wherein the negative feedback circuit comprises a preamplifier and a main wire, the preamplifier is connected with the output terminals, and the main wire is configured between the first element pair and second element pair and the configuring direction of the main wire is vertical with the pinning directions of the first element pair and the second element pair.

4. The electrical current sensing circuit according to claim 2, wherein the distance between the first element pair and the carrying-current electrical conductor is different from that between the second element pair and the carrying-current electrical conductor.

5. The electrical current sensing circuit according to claim 2, wherein the distance between the first element pair and the carrying-current electrical conductor is the same with that between the second element pair and the carrying-current electrical conductor.

6. The electrical current sensing circuit according to claim 2, wherein the first element pair has a first sensitivity and a first saturation point, and the second element pair has a second sensitivity and a second saturation point.

7. The electrical current sensing circuit according to claim 6, wherein the first sensitivity is equal to the second sensitivity, and the first saturation point is not equal to the second saturation point.

8. The electrical current sensing circuit according to claim 6, wherein the first sensitivity is not equal to the second sensitivity, and the first saturation point is not equal to the second saturation point.

9. A printed circuit board assembly comprising an electrical current sensing circuit, an analog-to-digital converter and a central processing unit connecting, wherein the electrical current sensing circuit comprises:
a Wheatstone bridge circuit having at least four magnetoresistive elements connecting and a pair of output terminals, the magnetoresistive elements adapted for sensing an external magnetic field with a first direction generated by a carrying-current electrical conductor, and outputting a differential signal; and
a negative feedback circuit connecting with the output terminals, actuated by the differential signal and generated a magnetic field with a second direction that is opposite to the first direction, thereby eliminating the impact of the temperature drift to the magnetoresistive element character.

10. The printed circuit board assembly according to claim 9, wherein the four magnetoresistive elements are divided into a first element pair and a second element pair that have two opposed pinning directions, which are perpendicular to the first direction of the external magnetic field.

11. The printed circuit board assembly according to claim 10, wherein the negative feedback circuit comprises a preamplifier and a main wire, the preamplifier is connected with the output terminals, and the main wire is configured between the first element pair and second element pair and the configuring direction of the main wire is vertical with the pinning directions of the first element pair and the second element pair.

12. The printed circuit board assembly according to claim 10, wherein the distance between the first element pair and the carrying-current electrical conductor is different from that between the second element pair and the carrying-current electrical conductor.

13. The printed circuit board assembly according to claim 10, wherein the distance between the first element pair and the carrying-current electrical conductor is the same with that between the second element pair and the carrying-current electrical conductor.

14. The printed circuit board assembly according to claim 10, wherein the first element pair has a first sensitivity and a first saturation point, and the second element pair has a second sensitivity and a second saturation point.

15. The printed circuit board assembly according to claim 14, wherein the first sensitivity is equal to the second sensitivity, and the first saturation point is not equal to the second saturation point.

16. The printed circuit board assembly according to claim 14, wherein the first sensitivity is not equal to the second sensitivity, and the first saturation point is not equal to the second saturation point.

17. An electrical current sensor device comprising at least one printed circuit board assembly, a holder for holding the printed circuit board assembly, a shielding cover covering on the holder for shielding an external magnetic field generated by external environment, and a display device formed on the shielding cover and connected with the printed circuit board assembly; wherein the printed circuit board assembly comprises an electrical current sensing circuit comprising:
a Wheatstone bridge circuit having at least four magnetoresistive elements connecting and a pair of output terminals, the magnetoresistive elements adapted for sensing an external magnetic field with a first direction generated by a carrying-current electrical conductor, and outputting a differential signal; and
a negative feedback circuit connecting with the output terminals, actuated by the differential signal and generated a magnetic field with a second direction that is opposite to the first direction, thereby eliminating the impact of the temperature drift to the magnetoresistive element character.
